(19) United States
(12) Patent Application Publication
(10) Pub. No.: US 2018/0067158 A1
(43) Pub. Date: Mar. 8, 2018

(54) VOLTAGE DETECTING DEVICE

(71) Applicant: Yazaki Corporation, Tokyo (JP)

(72) Inventor: Yoshihiro KAWAMURA, Makinohara-shi (JP)

(73) Assignee: Yazaki Corporation, Tokyo (JP)

(21) Appl. No.: 15/682,957

(22) Filed: Aug. 22, 2017

(30) Foreign Application Priority Data
Sep. 8, 2016 (JP) 2016-175424

(51) Int. Cl. G01R 31/02; H02J 7/00

(52) U.S. Cl. CPC G01R 31/025; H02J 7/0047

(57) ABSTRACT

The present invention is to provide a voltage detecting device connected to an ungrounded high-voltage battery which is connected to a high-voltage conducting path becoming a charge and discharge path, the voltage detecting device detecting at least one of a ground fault of a system in which the high-voltage battery is arranged and a voltage of the high-voltage battery. The voltage detecting device has a magnetic switch in which ON/OFF is switched based on magnetic field generated by current flowing through the high-voltage conducting path. The magnetic switch switches between a first measuring condition and a second measuring condition different from the first measuring condition in a measuring circuit or a measuring parameter.

### BACKGROUND OF THE INVENTION

### Technical Field

The present invention relates to a voltage detecting device for detecting at least one of a ground fault of a system in which a high-voltage battery is provided and a voltage of the high-voltage battery. The voltage detecting device is connected to an ungrounded high-voltage battery.

### Related Art

A vehicle such as a hybrid vehicle having an engine and an electric motor as a driving source or an electric vehicle charges a battery mounted in a vehicle body, and generates driving force by using an electric energy from the battery. In general, a battery-associated power circuit is configured as a high-voltage circuit for handling high-voltage of 200 V or more. Further, in order to ensure safety, the high-voltage circuit including the battery is ungrounded structure electrically insulated from the vehicle body which is the ground reference potential point.

In the vehicle mounting an ungrounded high-voltage battery, a voltage detecting device is provided so as to monitor a system in which the high-voltage battery is arranged, more specifically, an insulated condition (ground fault) between a main power system from the high-voltage battery to a motor and the vehicle body. For example, as described in Patent Literature 1, in the voltage detecting device, a system using a capacitor called a flying capacitor is widely used.

A flying capacitor type voltage detecting device switches measurement routes with a plurality of switching elements, and simultaneously repeats charge and discharge of the flying capacitor. Further, the flying capacitor type voltage detecting device gets insulation resistance based on a charge voltage, and detects a ground fault when the insulation resistance is lower than a criterion level.

In the measurement routes of a switching object, a route for measuring a voltage of the high-voltage battery is included. Therefore, the flying capacitor type voltage detecting device obtains a voltage of the high-voltage battery in a process detecting a ground fault. Further, the flying capacitor type voltage detecting device can obtain a voltage of the high-voltage battery independently of ground fault detection.

Patent Literature 1: JP 2013-205082 A

Patent Literature 2: JP 2016-118522 A

### SUMMARY OF THE INVENTION

A voltage detecting device makes a measurement under various measurement conditions such as a capacitance of a flying capacitor, charging time, and a ground fault criterion value. By those measurement conditions, detection accuracy, detection time, and noise resistance performance are changed. Meanwhile, if the measurement conditions of the voltage detecting device can be switched based on a charging and discharging state of a high-voltage battery, operation of the more flexible voltage detecting device can be performed.

For example, the measurement condition of the voltage detecting device can be switched to a measurement condition performing voltage measurement of the high-voltage battery at high speed with high accuracy when charging and discharging the high-voltage battery. Further, the measurement condition of the voltage detecting device can be switched to a measurement condition performing ground fault criterion excellent in noise resistance performance at the time other than charging and discharging.

Alternatively, when charging the high-voltage battery, the measurement condition of the voltage detecting device can be switched to a measurement condition performing the voltage measurement of the high-voltage battery at high speed with high accuracy. When discharging the high-voltage battery, the measurement condition of the voltage detecting device can be switched to a measurement condition performing the ground fault criterion excellent in noise resistance performance.

However, in order to switch the measurement condition of the voltage detecting device depending on a charging and discharging state of the high-voltage battery, it is necessary to wire a switching control line from an external control unit such as an ECU (engine control unit) for monitoring the charging and discharging state in the voltage detecting device.

Herein, the voltage detecting device is a high-voltage circuit connected to the high-voltage battery. On the other hand, the external control unit is a low-voltage circuit operating at a logic voltage of several volts. Since ensuring electrical insulation between the high-voltage circuit and the low-voltage circuit is required, it is not preferable to increase a number of control line from the low-voltage circuit to the high-voltage circuit.

Thus, an object of the present invention is to provide a voltage detecting device which can switch measuring conditions of the voltage detecting device depending on a charging and discharging state of a high-voltage battery without increasing control lines from a low-voltage circuit to a high-voltage circuit.

In order to solve the above issue, a voltage detecting device of the present invention is connected to an ungrounded high-voltage battery which is connected to a high-voltage conducting path becoming a charge and discharge path. The voltage detecting device detects at least one of a ground fault of a system in which the high-voltage battery is arranged and a voltage of the high-voltage battery. The voltage detecting device has a magnetic switch in which ON/OFF is switched based on magnetic field generated by current flowing through the high-voltage conducting path. The magnetic switch switches between a first measuring condition and a second measuring condition different from the first measuring condition in a measuring circuit or a measuring parameter.

Herein, the measuring circuit includes a capacitor. A capacitance of the capacitor is different between the first measurement condition and the second measurement condition.

Alternatively, the measuring circuit includes a voltage measuring capacitor.

Charging time of the voltage measuring capacitor is different between the first measurement condition and the second measurement condition. The charging time is included as the measuring parameter.

Alternatively, the voltage detecting device detects the ground fault of the system in which at least the high-voltage battery is arranged. The measuring circuit includes a voltage measuring capacitor. A conversion table is included as the measuring parameter so as to determine the ground fault based on a charging voltage of the voltage measuring capacitor. The conversion table is different between the first measuring condition and the second measuring condition.

According to the present invention, the measurement condition of the voltage detecting device can be switched based on a charging and discharging state of the high-voltage battery without increasing control lines from the low-voltage circuit to the high-voltage circuit.

### BRIEF DESCRIPTION OF THE DRAWINGS

FIG. 1 is a block diagram showing a configuration of a voltage detecting device according to a first embodiment of the present invention;

FIG. 2 is a diagram showing a measuring cycle for grasping insulation resistances RLp and RLn;

FIG. 3 is a diagram for explaining measuring time of charge voltage of a capacitor C1 for detection;

FIGS. 4A, 4B and 4C are diagrams for explaining a basic example of current flowing the high-voltage bus bar 320 and ON/OFF switching of the reed switch 141;

FIGS. 5A, 5B and 5C are diagrams for explaining current flowing in the high-voltage bus bar in consideration of a current direction and ON/OFF switching of the reed switch;

FIGS. 6A, 6B and 6C are diagrams for explaining current flowing in the high-voltage bus bar in consideration of the current direction and ON/OFF switching of the reed switch;

FIG. 7 is a block diagram showing a configuration of the voltage detecting device according to a second embodiment of the present invention;

FIG. 8A and 8B are a diagram for explaining switching of charging time of the capacitor C1 for detection; and

FIG. 9 is a block diagram showing a configuration of the voltage detecting device according to a third embodiment of the present invention.

### DESCRIPTION OF THE PREFERRED EMBODIMENT

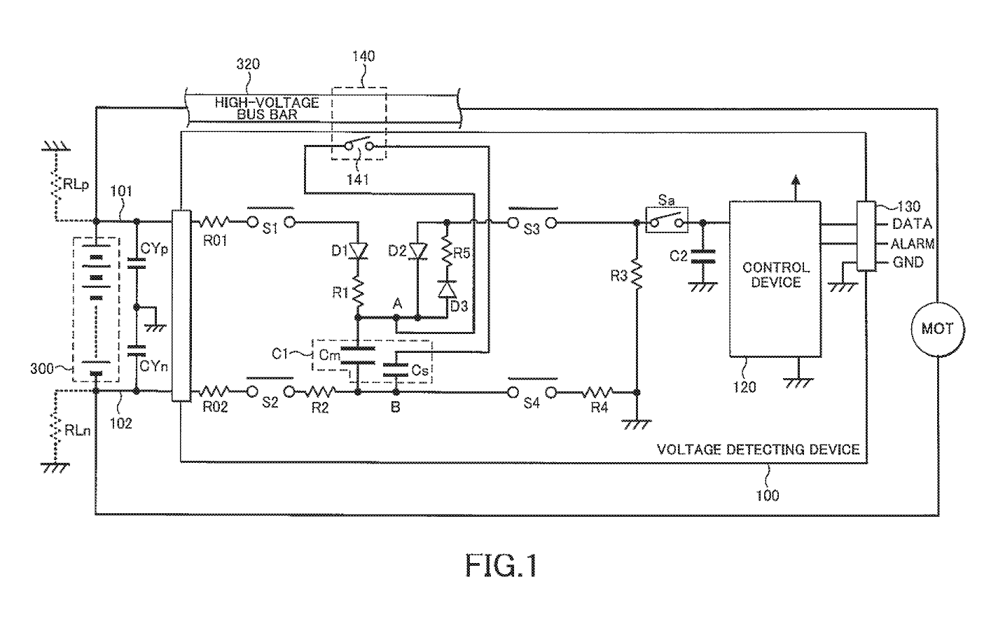

An embodiment of the present invention will be detail explained with reference to drawings. FIG. 1 is a block diagram showing a configuration of a voltage detecting device 100 according to a first embodiment of the present invention. As shown in FIG. 1, the voltage detecting device 100 is connected to an ungrounded high-voltage battery 300, and is a flying capacitor type device for detecting ground fault of a system in which the high-voltage battery 300 is arranged. Further, the voltage detecting device 100 is able to detect a voltage of the high-voltage battery 300 independently of detection of a ground fault.

Herein, an insulation resistance between a positive side of the high-voltage battery 300 and ground is represented as RLp, and an insulation resistance between a negative side thereof and ground is represented as RLn.

The high-voltage battery 300 is constructed by an electrifiable battery such as a lithium-ion battery and so on, discharges an electrical current via a high-voltage bus bar 320, and drives an electrical motor MOT connected through an inverter (not shown). Further, when regenerating or connecting with a charging facility (not shown), charging is performed via the high-voltage bus bar 320. Therefore, the high-voltage bus bar 320 becomes a conducting path of discharge current and charge current.

In order to eliminate high-frequency noise of power supply and to stabilize operation, capacitors CYp and CYn referred to as a Y capacitor (line bypass capacitor) are respectively connected between a positive side power line 101 of the high-voltage battery 300 and ground electrode, and between a negative side power line 102 and ground electrode. Herein, the Y capacitor may be omitted.

As shown in FIG. 1, the voltage detecting device 100 has a main capacitor for detection Cm, and a sub-capacitor for detection Cs which is connected via a magnetic switch unit 140 in parallel with the main capacitor for detection Cm. The main capacitor for detection Cm and the sub-capacitor for detection Cs can use for example a ceramic capacitor.

The main capacitor for detection Cm and the sub-capacitor for detection Cs are collectively referred to as a capacitor for detection C1. Herein, when the sub-capacitor for detection Cs is disconnected, a capacitance of the capacitor for detection C1 is equal to a capacitance of the main capacitor for detection Cm. When the sub-capacitor for detection Cs is connected, a capacitance of the capacitor for detection C1 is equal to composite capacitance of the main capacitor for detection Cm and the sub-capacitor for detection Cs. The capacitor for detection C1 is operated as a flying capacitor.

Further, in order to switch measuring path and control charge and discharge of the capacitor for detection C1, four switching elements S1-S4 are arranged around the capacitor for detection C1. Furthermore, a switching element Sa is arranged so as to sample a voltage for measuring corresponding to a charge voltage of the capacitor for detection C1. The switching element Sa is turned on when only sampling. Those switching elements are constructed by an insulation type switching element like an optical MOSFET.

One end of the switching element S1 is connected to the positive side power line 101 via a resistor R01, and the other end thereof is connected to an anode side of a diode D1. A cathode side of the diode D1 is connected to one end of a resistor R1, and the other end of the resistor R1 is connected to a connection point A.

One end of the switching element S2 is connected to a negative side power line 102 via a resistor R02, and the other end thereof is connected to one end of a resistor R2. The other end of the resistor R2 is connected to a connection point B.

One end of the switching element S3 is connected to one end of a resistor R5 and an anode side of a diode D2, and the other thereof is connected to one end of a resistor R3 and one end of the switching element Sa. A cathode side of the diode D2 is connected to the connection point A, the other end of the resistor R5 is connected to a cathode side of a diode D3, and an anode side of the diode D3 is connected to the connection point A. The other end of the resistor R3 is grounded.

One end of the switching element S4 is connected to the connection point B, and the other end thereof is connected to one end of a resistor R4. The other end of the resistor R4 is grounded. The other end of the switching element Sa is connected to one end of a capacitor C2 of which the other end is grounded and an analog input terminal of a control device 120.

One end of the main capacitor for detection Cm is connected to the connection point A, and the other end thereof is connected to the connection point B. Further, one end of the sub-capacitor for detection Cs is connected to the connection point A via the magnetic switch unit 140, and the other end thereof is connected to the connection point B.

The control device 120 is constructed with a microcomputer and so on, and executes various controls which is required for the voltage detecting device 100 by running a previously incorporated program. More specifically, the control device 120 controls the switching elements S1-S4 individually, and switches measuring path. Furthermore, the control device 102 controls charge and discharge of the capacitor C1 for detection.

Moreover, the control device 120 controls the switching element Sa, inputs an analog level corresponding to a charge voltage of the capacitor for detection C1 from the analog input terminal, performs a predetermined calculation based on the analog level, and obtains the insulation resistances RLp and RLn. A measurement data and an alarm are outputted to a control unit not shown via an output connector 130.

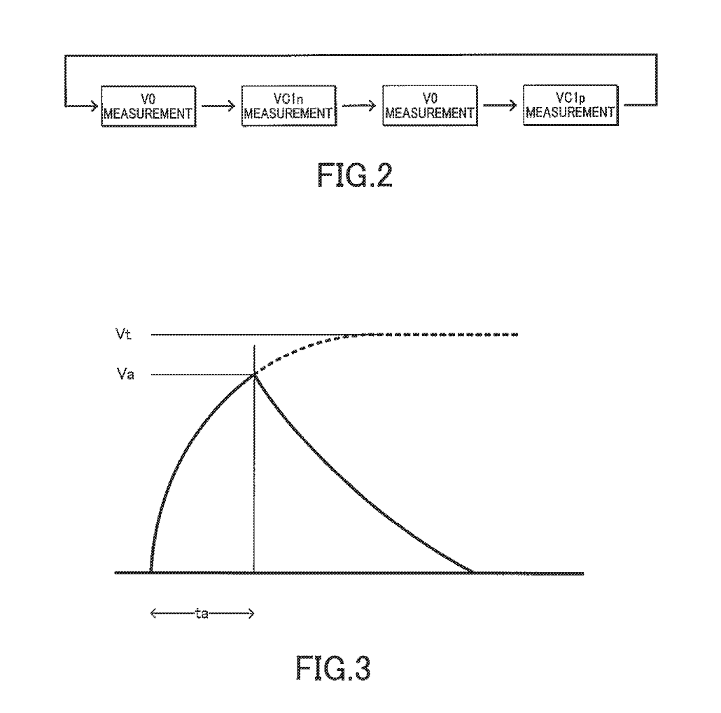

FIG. 2 shows a measuring cycle for obtaining the insulation resistances RLp and RLn. As shown in FIG. 2, the voltage detecting device 100 repeats measurement operation of V0 measurement period→VC1n measurement period V0 measurement period→VC1p measurement period in order as 1 cycle. All of the measurement period measures the charging voltage of the capacitor for detection C1 after charging the capacitor for detection C1 with a voltage of a measurement object. Then, for next measurement, the capacitor for detection C1 is discharged.

In the V0 measurement period, a voltage corresponding to a voltage of the high-voltage battery is measured. Therefore, the switching elements S1 and S2 are turned ON, the switching elements S3 and S4 are tuned OFF, and then the capacitor for detection C1 is charged. That is, the high-voltage battery 300, the resistor R01, the resistor R1, the capacitor for detection C1, the resistor R2, and the resistor R02 are a measurement path.

In this case, in order to shorten measurement time, as shown in FIG. 3, instead of completely charging the capacitor for detection C1, the charging voltage Va of a point in time to elapsed from charging start is measured, and a voltage Vt at full charge is calculated. This also applies to other measurement periods. Also, in FIG. 3, a horizontal axis represents time, and a vertical axis represents the charging voltage of the capacitor for detection C1.

When measuring the charging voltage Va, the switching elements S1 and S2 are turned OFF, the switching elements S3 and S4 are turned ON, and then sampling is performed in the control device 120. Thereafter, the switching element Sa is turned OFF, and the capacitor C1 is discharged so as to perform next measurement. When measuring the charging voltage Va, an operation during discharge of the capacitor for detection C1 is the same in other measurement periods.

In the VC1n measurement period, a voltage reflecting the effect of the insulation resistance RLn is measured. Therefore, the switching elements S1 and S4 are turned ON, the switching elements S2 and S3 are turned OFF, and then the capacitor for detection C1 is charged. That is, the high-voltage battery 300, the resistor R01, the resistor R1, the capacitor for detection C1, the resistor R2, ground, and the insulation resistance RLn are a measurement path.

In the VC1p measurement period, a voltage reflecting the effect of the insulation resistance RLp is measured. Therefore, the switching elements S2 and S3 are turned ON, the switching elements S1 and S4 are turned OFF, and then the capacitor for detection C1 is charged. That is, the high-voltage battery 300, the insulation resistance RLp, ground, resistor R3, the capacitor for detection C1, the resistor R2, and the resistor R02 are a measurement path.

It is known that (RLp×RLn)/(RLp+RLn) can be obtained based on (VC1p+VC1n)/V0 calculated from V0, VC1n, and VC1p obtained in these measurement periods. Therefore, by measuring V0, VC1n, and VC1p, it is possible to grasp the insulation resistances RLp and RLn. Meanwhile, a calculation formula for obtaining (RLp×RLn)/(RLp+RLn) is complex. Thus, in the control device 120, a conversion table is previously prepared, the insulation resistances RLp and RLn can be obtained based on (VC1p+VC1n)/V0 calculated from the measured V0, VC1n, and VC1p without performing complicated calculations. Further, when the insulation resistances RLp and RLn are equal to or smaller than a predetermined decision criterion level, it is determined that a ground fault has occurred and an alarm is outputted.

A magnetic switch unit 140 for switching connection/disconnection of the sub-capacitor for detection Cs has a reed switch 141 in which ON/OFF is switched by magnetic field. In the embodiment of the present invention, the reed switch 141 is turned ON/OFF by magnetic field generated from current flowing the high-voltage bus bar 320. Therefore, the reed switch 141 is disposed near the high-voltage bus bar 320 in such a direction that a longitudinal direction of a reed piece is in the same direction as the magnetic field generated by current flowing the high-voltage bus bar 320.

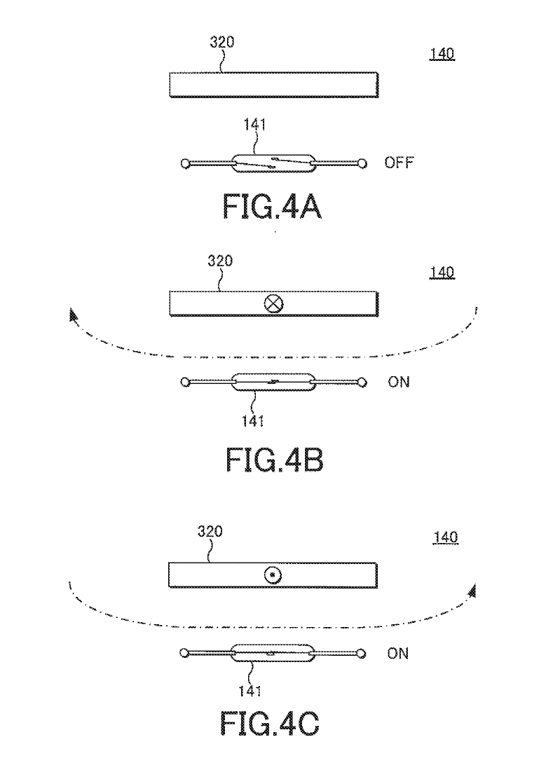

FIGS. 4A, 4B and 4C are diagrams for explaining a basic example of current flowing the high-voltage bus bar 320 and ON/OFF switching of the reed switch 141. As shown in FIG. 4A, when no current is flowing through the high-voltage bus bar 320, the reed switch 141 is kept at OFF state. On the other hand, as shown in FIG. 4B, when current is flowing from front to back in the figure, the reed piece is magnetized by magnetic field generated by current flowing through the high-voltage bus bar 320, and the reed switch 141 is turned ON. Furthermore, as shown in FIG. 4C, when current is flowing from back to front in the figure, the reed piece is magnetized by magnetic field generated by current flowing through the high-voltage bus bar 320, and the reed switch 141 is turned ON.

Also, when current of a predetermined amount or more flows, the reed switch 141 can be turned ON by adjusting a distance between the high-voltage 32 and the reed switch 141 or by selecting sensitively of the reed switch 141. In this case, in addition to when no current flows the high-voltage bus bar 320, even if current is flowing, the reed switch 141 is kept at OFF state when current is less than a predetermined amount. Similarly, in another example shown below, current amount for switching the reed switch 141 to an ON state can be adjusted.

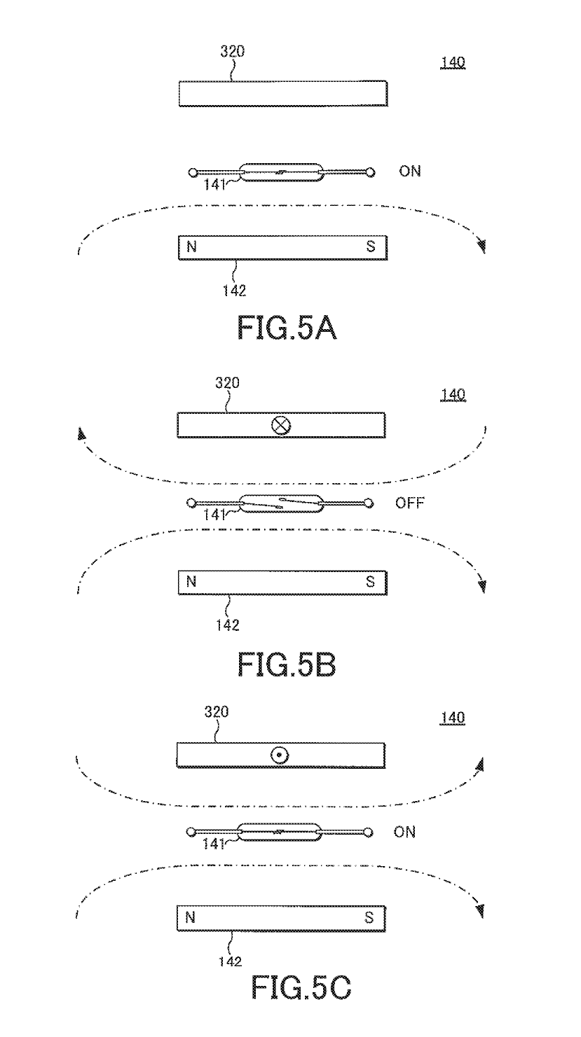

In the basic examples shown in FIGS. 4A, 4B and 4C, when current flows through the high-voltage bus bar 320, the reed switch 141 is turned ON regardless of a current direction. However, as shown in FIGS. 5A, 5B and 5C, it is possible to change ON/OFF switching operation according to the current direction by using a permanent magnet 142 located in an opposite side of the high-voltage bus bar 320.

More specifically, as shown in FIG. 5A, when no current flows through the high-voltage bus bar 320, the reed switch 141 is turned ON by magnetic field generated by the permanent magnet 142. As shown in FIG. 5B, when current flows through the high-voltage bus bar 320 from front to back in the figure, the magnetic field generated by the permanent magnet 142 and the magnetic field generated by current flowing the high-voltage bus bar 320 cancel each other. Thereby, the reed switch 141 is turned OFF. As shown in FIG. 5C, when current flows through the high-voltage bus bar 320 from front to back in the figure, the magnetic field generated by the permanent magnet 142 and the magnetic field generated by current flowing the high-voltage bus bar 320 strengthen each other. Thereby, the reed switch 141 is turned ON.

In this manner, by using the permanent magnet 142, control that the reed switch 141 is turned OFF can be performed only when current in a predetermined direction flows through the high-voltage bus bar 320. Further, by adjusting a direction or position of the permanent magnet 142, control that the reed switch 141 is turned ON can be performed only when current in a predetermined direction flows through the high-voltage bus bar 320. Of course, only when current of a predetermined amount or more in a predetermined direction flows through the high-voltage bus bar 320, control that the reed switch is turned ON or OFF can be performed.

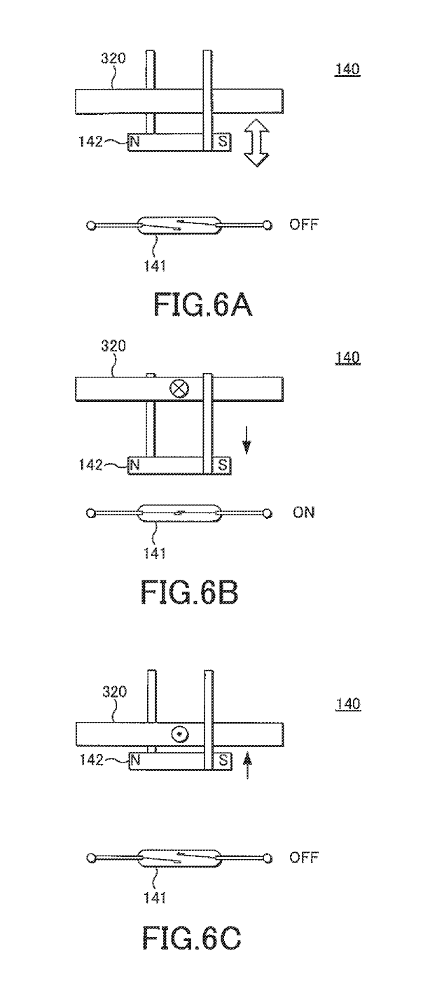

Alternatively, as shown in FIGS. 6A, 6B and 6C, the permanent magnet 142 is arranged between the high-voltage bus bar 320 and the reed switch 141 in the same direction as magnetic field generated by current flowing though the high-voltage bus bar 320 or in a direction generating magnetic field of the reverse direction. Further, the permanent magnet 142 is provided under a movable state between the high-voltage bus bar 320 and the reed switch 141. Thereby, ON/OFF switching operation can be changed according to a current direction.

As shown in FIG. 6A, in a stage that no current flows through the high-voltage bus bar 320, the permanent magnet 142 is stabilized at a prescribed position. In this position, the reed switch 141 cannot be turned ON in magnetic field generated by the permanent magnet 142. Thus, the reed switch 141 is kept at an OFF state.

As shown in FIG. 6B, when current flows through the high-voltage bus bar 320 from front to back in the figure, the permanent magnet 142 receives a force in a direction away from the high-voltage bus bar 320, and thereby moves to approach the reed switch 141. As a result, the reed switch 141 is turned ON by magnetic field generated by the permanent magnet 142.

Meanwhile, as shown in FIG. 6C, when current flows through the high-voltage bus bar 320 from front to back in the figure, the permanent magnet 142 receives a force in a direction approaching the high-voltage bus bar 320, and thereby moves in a direction away from the reed switch 141. As a result, the reed switch 141 is turned OFF.

In any cases, the sub-capacitor for detection Cs is connected in a state that the reed switch 141 is turned ON, and the sub-capacitor for detection Cs is disconnected in a state that the reed switch 141 is turned OFF. Meanwhile, by using an element for reversing ON/OFF, it is easily possible to connect the sub-capacitor for detection Cs in a state that the reed switch 141 is turned OFF and disconnect the sub-capacitor for detection Cs in a state that the reed switch 141 is turned ON.

In this manner, by using the magnetic switch unit 140 including the reed switch 141, connection/disconnection of the sub-capacitor for detection Cs can be arbitrarily switched according to the presence or absence of current flowing the bus bar 320 (it is a concept including the presence or absence of current of a predetermined amount or more). Further, by using the magnetic switch unit 140 combining the reed switch 141 and the permanent magnet 142, connection/disconnection of the sub-capacitor for detection Cs can be switched based on a current direction flowing the high-voltage bus bar 320 (it is a concept including the current direction of a predetermined amount or more).

Also, combination of the above reed switch 141 and the permanent magnet 142 is illustrated as one example. Thus, connection/disconnection of the sub-capacitor for detection Cs may be switched based on a current direction flowing the high-voltage bus bar 320 by using the magnetic switch unit 140 of another combination.

Herein, the presence or absence of current flowing the high-voltage bus bar 320 and the current direction flowing the high-voltage bus bar 320 corresponds to a charge/discharge state of the high-voltage battery 300. In other words, when the high-voltage battery 300 is charged/discharged, current flows through the high-voltage bus bar 320, and the flowing direction during charging is in a direction the reverse of discharging. At other times, current does not flow through the high-voltage bus bar 320.

In the first embodiment, when the sub-capacitor for detection Cs is connected, the capacitance of the capacitor for detection C1 is larger than that when the sub-capacitor for detection Cs is disconnected. When comparing a case that the capacitance of the capacitor for detection C1 is large to a case that the capacitance thereof is small, the smaller the capacitance is charged at high speed. For this reason, the charging voltage Va in charging time ta (see in FIG. 3) becomes large. Therefore, highly accurate measurement of high signal/noise ratio can be performed when the capacitance of the capacitor for detection C1 is smaller. On the other hand, effect of Y capacitor or floating capacitance is suppressed to be small as the capacitance is larger, and thereby measurement accuracy can be increased.

Also, when connection/disconnection of the sub-capacitor for detection Cs is switched, and the capacitance of the capacitor for detection is changed, the measured charging voltage Va is rapidly changed. The control device 120 determines connection/disconnection of the sub-capacitor for detection Cs by detecting a rapid change of the charging voltage, and the calculation formula of the voltage Vt in full charge is switched.

In the first embodiment, the capacitance of the capacitor for detection C1 is changed as the measurement condition regarding the measuring circuit, and thereby for example it is possible to perform an operation as shown below. Of course, it is not limited to the operation example shown below.

Operation example 1): when charging the high-voltage battery 300, the reed switch 141 is turned OFF, and the capacitance of the capacitor for detection C1 is set to be small. In this time, the voltage detecting device 100 is function as a voltage sensor. As discussed previously, the smaller the capacitance of the capacitor for detection C1 is, the larger the charging voltage Va becomes at the same charging time ta. Therefore, high accurate measurement can be performed with high S/N ratio.

Furthermore, when discharging the high-voltage battery 300, the reed switch 141 is turned OFF, and the capacitance of the capacitor for detection C1 is set to be large. At this time, the voltage detecting device 100 is function as a ground fault sensor. As described above, as the capacitance of the capacitor for detection C1 is large, effects of Y-capacitor and floating capacitance can be decreased. Therefore, accurate measurement can be improved.

Moreover, making the voltage detecting device 100 functioning as the voltage sensor or ground fault sensor can mean that for example performing a series of measurement and then emphasizing on the voltage measurement function or ground fault detection function. Alternatively, it may mean that halting one of the function and performing measurement of the other thereof. When the ground fault detection function is stopped and the voltage detecting device 100 functions as the voltage sensor, VC1n measurement period and VC1p measurement period can be eliminated. Therefore, a cycle of voltage measurement can be reduced, and high speed and high accurate voltage measurement can be performed.

Herein, switching of the function can be performed by using the control device 120 detecting a rapid change in charging voltage similar to the switching or the calculation formula of the voltage Vt.

The operation example shown in the first embodiment is not a switching control performed from an external control unit, but it is a switching control to be completed in the voltage detecting device 100. For this reason, the operation example can be performed without increasing a control line from the external control unit to the voltage detecting device 100. Therefore, according to the first embodiment of the present invention, the measurement condition of the voltage detecting device can be switched by a charging and discharging state of the high-voltage battery without increasing control lines from a low-voltage circuit to a high-voltage circuit.

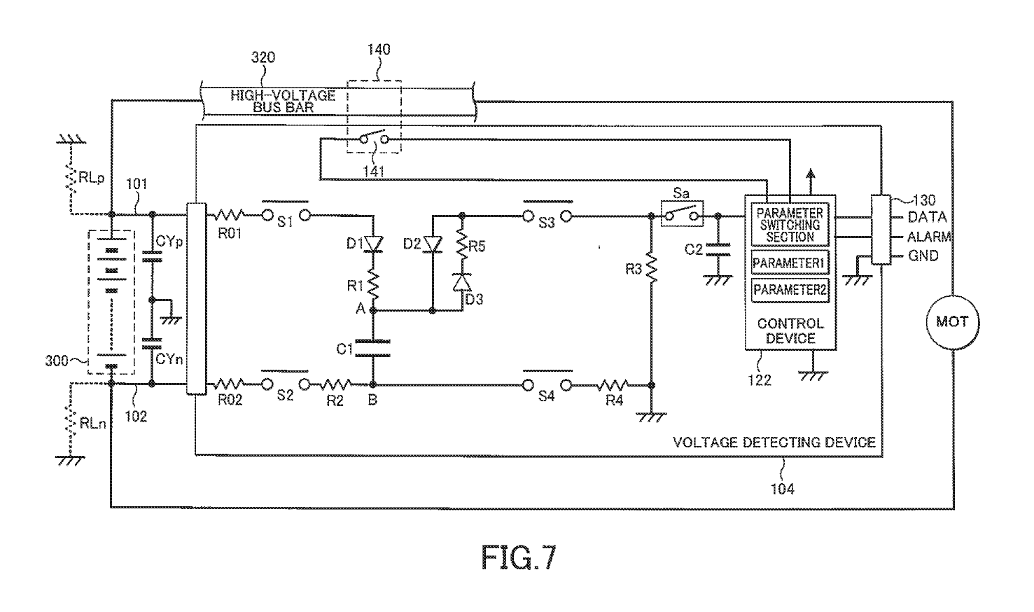

Next, a second embodiment of the present invention will be explained. FIG. 7 is a block diagram showing a structure of a voltage detecting device 104 according to the second embodiment of the present invention. The same numeral reference is assigned to the same structure as the voltage detecting device 100 of the first embodiment, and the description thereof is omitted.

In the voltage detecting device 100 according to the first embodiment, the capacitance of the capacitor for detection C1 in the measuring circuit as the measurement condition is changed. Meanwhile, in the voltage detecting device 104 according to the second embodiment, as the measurement condition, a measuring parameter used in the control device 122 so as to measure is changed.

Therefore, as a flying capacitor, the capacitor for detection C1 of which the capacitance is fixed is used. Further, the control device 122 has a parameter switching section, a parameter 1, and a parameter 2. The parameter switching section switches the parameter 1 to the parameter 2 as a detection parameter based on the magnetic switch unit 140. The ON/OFF switching control of the magnetic switch unit 140 can be the same as in the first embodiment.

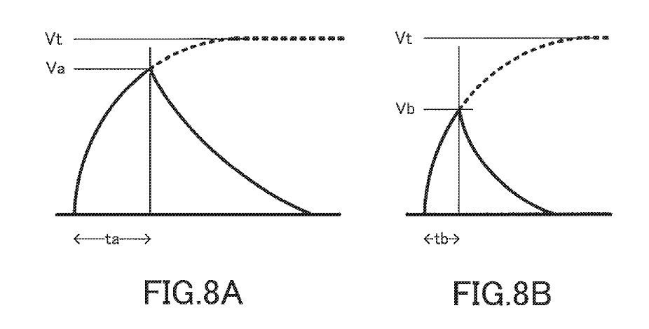

As shown in FIG. 8, the parameter 1 and the parameter 2 switched by the parameter switching section can become charging times of the capacitor for detection C1 in each of measurement periods as a first example. That is, the charging time to is set as the parameter 1, and the charging time tb (<ta) is set as the parameter 2.

When comparing the charging time ta with the charging time tb shorter than it, measurement time of the charging time tb is short, and thereby measurement can be performed at high speed. On the other hand, the charging voltage Va of the charging time ta is higher than the charging voltage Vb of the charging time tb. For this reason, in the charging time ta, high accuracy measurement of high S/N ratio can be performed. For example, when a motor MOT is operated, in other words, when the high-voltage battery 300 is discharged, noise of the motor becomes larger. Therefore, high accuracy measurement of the high S/N ratio is effective.

Thus, in the first example of the second embodiment, for example, operation can be performed as shown below by changing the charging time of the capacitor for detection C1 as the measurement condition regarding to the measurement parameter. Of course, it is not limited to the operation example shown below.

Operation example 2): during discharging of the high-voltage battery 300, when current of a predetermined amount or more flows through the bus bar 320, the charging time of the capacitor for detection C1 is increased. Thereby, at a discharging time in which current of a predetermined amount or more flows, high accuracy measurement of high S/N ratio hardly affected by the influence of the motor noise is performed. In other cases, measurement can be performed at a high speed.
Operation example 3): during charging and discharging of the high-voltage battery 300, when current of a predetermined amount or more flows through the bus bar 320, the charging time of the capacitor for detection C1 is increased. Thereby, at the charging and discharging time in which current of a predetermined amount or more flows, high accuracy measurement of high S/N ratio is performed. In other cases, measurement can be performed at a high speed.
Operation example 4): during charging of the high-voltage battery 300, the charging time is decreased. Thereby, when charging the high-voltage battery 300, measurement can be performed at a high speed. In other cases, high accuracy measurement of high S/N ratio can be performed.

As a second example, the parameter 1 and the parameter 2 switched by the parameter switching section may be a conversion table. That is, the conversion table used to obtain the insulation resistances RLp and RLn based on (VC1p +VC1n)/V0 obtained from the measured V0, VC1n and VC1p is switched based on ON/OFF of the magnetic switch unit 140.

The control device 122 determines that a ground fault is generated when the insulation resistances RLp and RLn are equal to or smaller a predetermined decision criterion level obtained from the conversion table, and then outputs an alarm. However, the obtained insulation resistances RLp and RLn include error affected by noise. For this reason, it is safety preferable to decrease a threshold value when outputting an alarm as the noise becomes larger as the error is large.

Therefore, a normal conversion table is prepared as the parameter 1, and a conversion table in which the insulation resistance is evaluated low is prepared as the parameter 2. As a cause of noise, as described above, the motor noise when discharging the high-voltage battery 300 is considered. Thus, in a second example of the second embodiment, the conversion table is switched as the measurement condition regarding to the measuring parameter, and thereby for example it is possible to perform operations as shown below. Of course, it is limited to the following operation example.

Operation example 5): during discharging of the high-voltage battery 300, when current of a predetermined amount or more flows through the bus bar 320, the normal conversion table is switched to the conversion table in which the insulation resistance is evaluated low. Thereby, operation that an alarm in consideration of error due to the motor noise is outputted can be performed.

Also, instead of the conversion table, the decision criterion level when outputting an alarm may be used as a parameter switched by the parameter switching section. More specifically, during discharging of the high-voltage battery 300, when current of a predetermined amount or more flows through the bus bar 320, the decision criterion level is switched to the decision criterion level in which a ground fault is more likely to be judged.

The operation example shown in the second embodiment is not a switching control from the external control unit but is a switching control which is completed in the voltage detecting device 104. Therefore, it can be performed without increasing control lines from the external control unit to the voltage detecting device 104. Thus, according to the second embodiment, the measurement condition of the voltage detecting device can be switched depending on a charging and discharging state of the high-voltage battery without increasing control lines from a low-voltage circuit to a high-voltage circuit.

Also, as the measurement condition switched based on a charging and discharging state of the high-voltage battery, the measuring circuit shown in the first embodiment may be combined with the measuring parameter shown in the second embodiment. That is, both the measuring circuit and the measuring parameter may be switched depending on a charging and discharging state of the high-voltage battery.

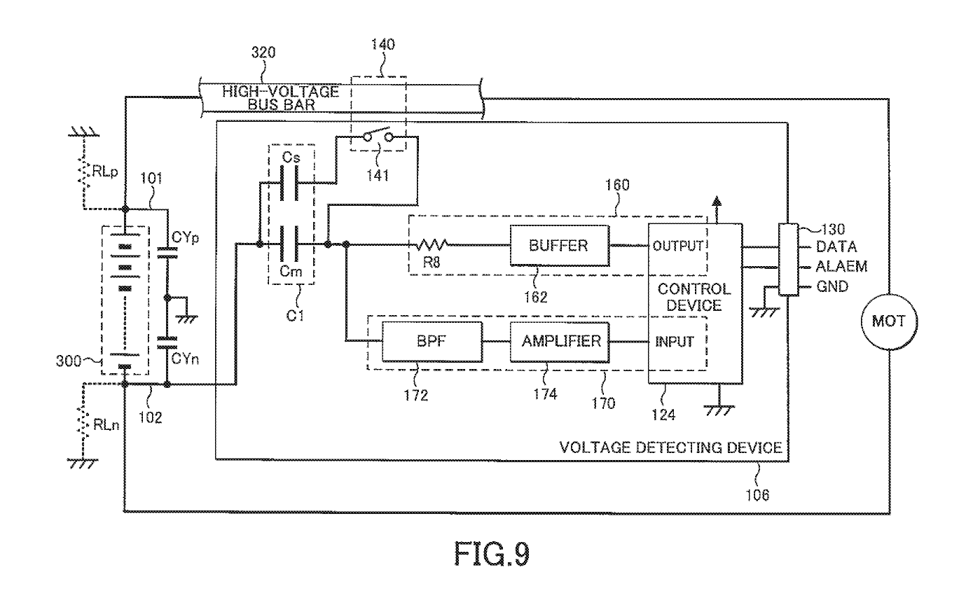

In the above embodiments, the flying capacitor type voltage detecting device is explained. However, the present invention can be applied to a coupling capacitor type voltage detecting device as described in Patent Literature 2. Herein, as a third embodiment of the present invention, a case that the present invention is applied to a coupling capacitor type voltage detecting device 106 for detecting a ground fault of a system in which a high-voltage battery is arranged will be explained with reference to FIG. 9.

As shown in drawings, the coupling capacitor type voltage detecting device 106 has a main coupling capacitor Cm, and a sub-coupling capacitor Cs. The sub-coupling capacitor Cs is connected to the main coupling capacitor Cm in parallel via the magnetic switch unit 140. Including the main coupling capacitor Cm and the sub-coupling capacitor Cs is referred to as the coupling capacitor C1.

Further, the voltage detecting device 106 includes a control device 124 having an output terminal for outputting a pulse voltage and an input terminal for inputting an analog signal, a buffer 162, a resistor R8, a bandpass filter (BPF), and an amplifier 174. a pulse generation unit 160 is constructed with the output terminal, the buffer 162 and the resistor R8 which are connected in series, and connected to one end of the coupling capacitor C1. A voltage detecting unit 170 is constructed with the BPF 172, the amplifier 174 and the input terminal which are connected in series, and connected to one end of the coupling capacitor C1. The other end of the coupling capacitor C1 is connected to the negative side power line 102.

In the coupling capacitor type voltage detecting device 106, a pulse outputted by the pulse generation unit 160 with a predetermined frequency is supplied to one end of the coupling capacitor C1. The pulse is supplied to the negative side power line 102 of the high-voltage battery 300 via the coupling capacitor C1. At this time, the voltage detecting device 170 detects a change of an amplitude level of voltage to ground in the coupling capacitor C1, and the control device 124 detects a degradation of the insulation resistance by comparing the change of the amplitude level with a threshold value.

In the voltage detecting device 106 according to the third embodiment, the capacitance of the coupling capacitor C1 in the measuring circuit is changed as the measurement condition. Thereby, according to a charging and discharging state of the high-voltage battery 300, for example, it is possible to switch between high speed ground fault detection and high accuracy ground fault detection. Alternatively, the pulse frequency of the measuring parameter may be changed as the measurement condition. Further, both the capacitance of the coupling capacitor C1 and the pulse frequency may be changed.

Furthermore, the reed switch 141 is connected to the bandpass filter (BPF) 172, and thereby when discharging current is large, that is, motor noise is large, filter condition is changed. For example, an operational amplifier used in the bandpass filter (BPF) 172 is made two stages. Thereby, decrease rate near the cutoff frequency becomes precipitous inclination. Alternatively, constant number of R and C may be changed so as to decrease the cutoff frequency.

These control examples are not a switching control from the external control unit but is a switching control completed in the voltage detecting device 106. Therefore, they can be performed without increasing control lines from the external control unit to the voltage detecting device 106. Thus, according to the third embodiment of the preset invention, the measurement condition of the voltage detecting device can be switched by a charging and discharging state of the high-voltage battery without increasing control lines from a low-voltage circuit to a high-voltage circuit.

The embodiments of the present invention have been described above. The present invention is not limited to the above embodiments. Various change and modifications can be made with the scope of the present invention. For example, as a switching object of the measurement circuit, not only the capacitor but also the resistance may be switched. Further, as a magnetic switch unit, not only the reed switch but also a magnetic field detection element such as a hall element, magnetic impedance and so on may be used.

### REFERENCE SINGS LIST

1 voltage detecting device

101 positive side power line

102 negative side power line

104 voltage detecting device

106 voltage detecting device

120 control device

122 control device

124 control device

130 output connector

140 magnetic switch unit

141 reed switch

142 permanent magnet

160 pulse generation unit

162 buffer

170 voltage detecting unit

172 BPF

174 amplifier

300 high-voltage battery

320 high-voltage bus bar

What is claimed is:

1. A voltage detecting device connected to an ungrounded high-voltage battery which is connected to a high-voltage conducting path becoming a charge and discharge path, the voltage detecting device detecting at least one of a ground fault of a system in which the high-voltage battery is arranged and a voltage of the high-voltage battery, the voltage detecting device comprising:
a magnetic switch in which ON/OFF is switched based on magnetic field generated by current flowing through the high-voltage conducting path, the magnetic switch switching between a first measuring condition and a second measuring condition different from the first measuring condition in a measuring circuit or a measuring parameter.

2. The voltage detecting device according to claim 1, wherein the measuring circuit includes a capacitor, and
a capacitance of the capacitor is different between the first measurement condition and the second measurement condition.

3. The voltage detecting device according to claim 1, wherein the measuring circuit includes a voltage measuring capacitor,
charging time of the voltage measuring capacitor is different between the first measurement condition and the second measurement condition, the charging time being included as the measuring parameter.

4. The voltage detecting device according to claim 1, wherein the voltage detecting device detects the ground fault of the system in which at least the high-voltage battery is arranged,
the measuring circuit includes a voltage measuring capacitor,
a conversion table is included as the measuring parameter so as to determine the ground fault based on a charging voltage of the voltage measuring capacitor, and
the conversion table is different between the first measuring condition and the second measuring condition.
